(19) United States
(12) Patent Application Publication
(10) Pub. No.: US 2015/0250076 A1
(43) Pub. Date: Sep. 3, 2015

(54) DATA CENTER, COMPUTER-READABLE RECORDING MEDIUM HAVING STORED THEREIN CONTROLLING PROGRAM FOR CONTROL APPARATUS AND CONTROLLING METHOD FOR DATA CENTER

(71) Applicant: FUJITSU LIMITED, Kawasaki-shi (JP)

(72) Inventor: Reiko Kondo, Yamato (JP)

(21) Appl. No.: 14/608,255

(22) Filed: Jan. 29, 2015

(30) Foreign Application Priority Data
Feb. 28, 2014 (JP) 2014-038445

(51) Int. Cl. H05K 7/20

(52) U.S. Cl. CPC H05K 7/20836; H05K 7/20736

(57) ABSTRACT

A data center includes plurality of electronic apparatus; a plurality of air conditioning apparatus individually corresponding to the plurality of electronic apparatus; and a control apparatus that controls the plurality of air conditioning apparatus. The control apparatus includes a processor. The processor controls a cooling capacity of each of the plurality of air conditioning apparatus. When a failure occurs in a first air conditioning apparatus from among the plurality of air conditioning apparatus, the processor allocates a cooling capacity of the first air conditioning apparatus to a second air conditioning apparatus from among the plurality of air conditioning apparatus based on setting information determined in advance.

### CROSS-REFERENCE TO RELATED APPLICATION

This application is based upon and claims the benefit of priority of the prior Japanese Patent Application No. 2014-038445, filed on Feb. 28 2014, the entire contents of which are incorporated herein by reference.

### FIELD

The present invention relates to a data center, a computer-readable recording medium having stored therein a controlling program for a control apparatus and a controlling method for a data center.

### BACKGROUND

In a data center in which a plurality of electronic apparatus such as information processing apparatus like servers, storage apparatus or communication apparatus are provided, an air conditioning apparatus for cooling the electronic apparatus and so forth is provided in many cases.

FIGS. 13 and 14 are views depicting an example of a configuration of a container type data center (hereinafter referred to simply as data center) 100, and FIG. 13 is a side elevational view and FIG. 14 is a top plan view. It is to be noted that illustration of a duct 114 is omitted in FIG. 14.

In recent years, a container type data center 100 exemplified in FIGS. 13 and 14 is known which includes, as a unit, a container 110 that accommodates a plurality of racks 111 in each of which a server 112 is incorporated therein and a plurality of air conditioning apparatus 120.

The container 110 is configured using, for example, a container for cargo transport or the like as a basis, and the inside of the container 110 is partitioned into two regions of a cold aisle and a hot aisle across the plurality of racks 111 as a boundary.

The racks 111 are provided on the boundary between the cold aisle and the hot aisle and individually have one or more servers 112 mounted thereon. Each of the servers 112 is provided in a rack 111 such that the front face thereof through which air is taken in is directed the cold aisle side and the rear face through which air is exhausted is directed the hot aisle side. Further, the server 112 takes in cooling wind (cooling air) from the cold aisle and exhausts the cooling wind (hot air) having passed through the inside thereof from the rear face thereof at the hot aisle side.

It is to be noted that one or more ducts 114 for introducing the cooling wind (hot air) having passed through the servers 112 to the plurality of air conditioning apparatus 120 are provided at an upper portion of the hot aisle region of the container 110.

The air conditioning apparatus 120 generates cooling wind that is to pass (cool) one or more servers 112 provided on the racks 111 in the container 110. Each of the plurality of air conditioning apparatus 120 includes a cooling unit 121 and one or more fans 122, and cools air from the hot aisle introduced thereto through the ducts 114 using the cooling unit 121 and sends out the air cooled in this manner as cooling wind (cold air) to the cold aisle by the fans 122.

By such a configuration as described above, the servers 112 provided in the racks 111 can take in cooling wind (cold air) blown to the front face thereof from the cold aisle side by the plurality of air conditioning apparatus 120 and exhaust the cooling wind from the rear face thereof to the hot aisle side. Consequently, the servers 112 in the container type data center 100 can be cooled efficiently.

It is to be noted that, as a related art, a technology is known which utilizes a virtualization technology to move a load on some of a plurality of servers placed in various operating conditions to some other servers (physical servers). For example, a technology is known wherein a data processing load is allocated preferentially to an Information and Communication Technology (ICT) apparatus disposed at a position at which the cooling supply easiness is high (refer, for example, to Patent Document 1). Also a technology is known wherein, in a system for determining a re-circulation index value of an airflow in a data center, workload allocation is changed in response to an index value of air re-circulation (refer, for example, to Patent Document 2).

[Patent Document 1] Japanese Laid-Open Patent Publication No. 2012-104576

[Patent Document 2] Japanese National Publication of International Patent Application No. 2007-505285

The installation number, individual cooling capacities and so forth of the air conditioning apparatus 120 are frequently designed or selected in response to the number, power consumption, disposition and so forth of electronic apparatus provided in the inside of the data center 100. In the data center 100 in which a plurality of air conditioning apparatus 120 designed or selected in such a manner as just described are provided, if some air conditioning apparatus 120 from among the plurality of air conditioning apparatus 120 is stopped by a failure or the like, then the remaining air conditioning apparatus 120 may be difficult to cool all of the electronic apparatus sufficiently. In this case, the temperature in the inside of the electronic apparatus rises and, in the worst case, some electronic apparatus may stop from a failure (or for trouble avoidance).

Therefore, in the data center 100, a greater number of air conditioning apparatus 120 than a sufficient number of air conditioning apparatus 120 for cooling all of the electronic apparatus upon normal operation of the electronic apparatus are occasionally incorporated to provide redundancy to the air conditioning apparatus 120. However, if redundancy is provided to the air conditioning apparatus 120, then some unnecessary air conditioning apparatus 120 are cased to operate in order to maintain the redundancy. Therefore, the air conditioning apparatus 120 excessively cool the inside of the data center 100 and consume surplus electric power.

In the related art described above, a case in which some air conditioning apparatus 120 from among the plurality of air conditioning apparatus 120 is stopped by a failure is not taken into consideration.

The data center 100 has a subject that, when some air conditioning apparatus 120 from among the plurality of air conditioning apparatus 120 is stopped by a failure in this manner, it is sometimes difficult to continue the processing of the electronic apparatus.

While the data center is described here taking the container type data center 100 depicted in FIGS. 13 and 14 as an example, there is the possibility that the subject described above may occur similarly also in various data centers in which a plurality of racks 111 in each of which one or more servers 112 are provided are accommodated. For example, the data centers include not only the container type data center 100 but also a modular type data center that can be flexibly constructed from units of elements such as a building, an air conditioning apparatus and so forth, a server rack including an air conditioning apparatus and so forth. Further, the data centers include also various facility type data centers such as an Internet Data Center (IDC).

### SUMMARY

According to an aspect of the embodiments, a data center includes a plurality of electronic apparatus, a plurality of air conditioning apparatus individually corresponding to the plurality of electronic apparatus, and a control apparatus that controls the plurality of air conditioning apparatus. The control apparatus includes a processor. The processor controls a cooling capacity of each of the plurality of air conditioning apparatus. When a failure occurs in a first air conditioning apparatus from among the plurality of air conditioning apparatus, the processor allocates a cooling capacity of the first air conditioning apparatus to a second air conditioning apparatus from among the plurality of air conditioning apparatus based on setting information determined in advance.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a schematic side elevational view depicting an example of a configuration of a container type data center according to an embodiment;

FIG. 2 is a schematic top plan view depicting an example of the configuration of the container type data center according to the embodiment;

FIG. 3 is a block diagram depicting an example of a configuration of hardware of a server depicted in FIG. 1;

FIG. 4 is a block diagram depicting an example of a functional configuration of a management server depicted in FIG. 1;

FIG. 5 is a view depicting an example of a cooling capacity management table retained by the management server depicted in FIG. 4;

FIGS. 6A and 6B are views illustrating the cooling capacity management table;

FIGS. 7 and 8 are views depicting examples of a cooling capacity to be allocated to a plurality of air conditioning apparatus depicted in FIG. 2;

FIG. 9 is a view illustrating a method of allocating, when plural ones of the air conditioning apparatus depicted in FIG. 2 fail, the cooling capacity of the failing air conditioning apparatus to the other air conditioning apparatus;

FIGS. 10 and 11 are flow charts illustrating examples of a controlling process for the air conditioning apparatus in the data center depicted in FIG. 1;

FIG. 12 is a schematic view illustrating a processing procedure by the management server depicting in FIG. 4 when an air conditioning apparatus stops;

FIG. 13 is a schematic side elevational view depicting an example of a configuration of a container type data center; and

FIG. 14 is a top plan view depicting an example of the configuration of the container type data center.

### DESCRIPTION OF EMBODIMENTS

In the following, an embodiment is described with reference to the drawings.

### [1] Embodiment

### [1-1] Configuration of the Data Center

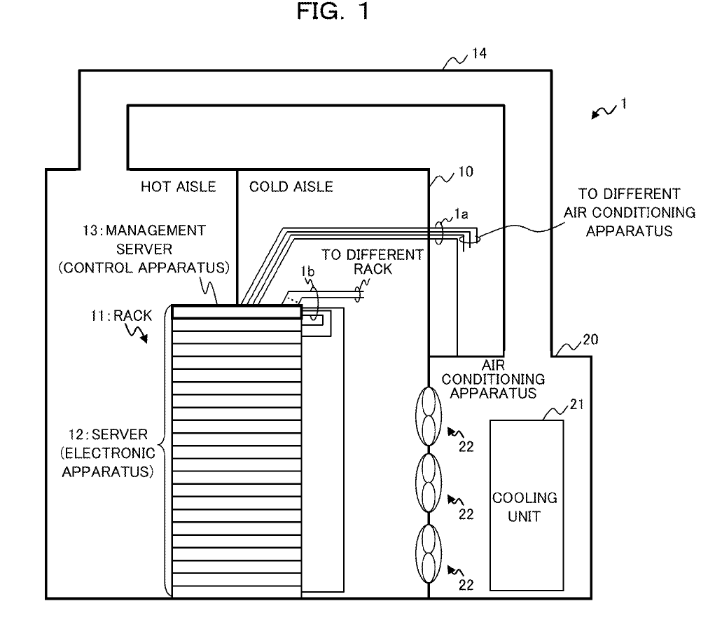

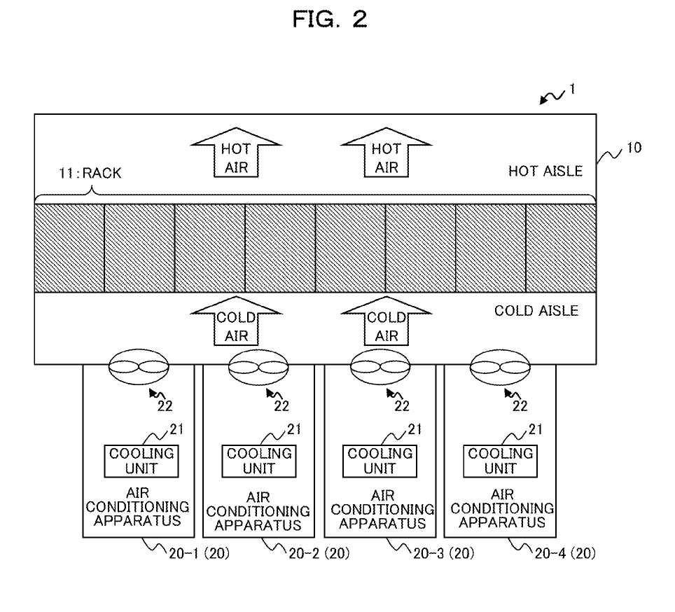

A configuration of a data center 1 as an example of the embodiment is described with reference to FIGS. 1 and 2.

FIGS. 1 and 2 are schematic views depicting an example of a configuration of the container type data center (hereinafter referred to simply as data center) 1, and FIG. 1 is a side elevational view and FIG. 2 is a top plan view. It is to be noted that illustration of a duct 14 is omitted in FIG. 2.

As depicted in FIGS. 1 and 2, the container type data center 1 as an example of the data center 1 according to the embodiment includes a container 10 and a plurality of (in FIG. 2, four) air conditioning apparatus 20-1 to 20-4. In the following description, where an arbitrary one of the air conditioning apparatus 20-1 to 20-4 is to be indicated, it is referred to simply as air conditioning apparatus 20.

The container 10 is configured using, for example, a cargo transport container or the like as a base therefor and accommodates a plurality of (in FIG. 2, eight) racks 11 therein. As depicted in FIG. 1, the inside of the container 10 is partitioned into two regions of a cold aisle and a hot aisle across the rack 11 as a boundary. In the cold aisle, the container 10 includes openings that communicate the container 10 and the air conditioning apparatus 20 (blowing entrances of fans 22) with each other at positions at which airflows in from the conditioning apparatus 20.

The racks 11 are provided at the boundary between the cold aisle and the hot aisle and individually include one or more (in the example of FIG. 1, a plurality of) servers (electronic apparatus).

Each server 12 is provided such that the front face thereof through which air is to be taken in is directed to the cold aisle side and the rear face thereof through which air is to be exhausted is directed to the hot aisle side. Further, the server 12 takes in cooling wind (cold air) from the cold aisle and exhausts cooling wind (hot air) having passed through the inside of the server 12 from the rear face thereof at the hot aisle side.

It is to be noted that one or more ducts 14 for guiding cooling wind (hot air) having passed through the servers 12 individually to the plurality of conditioning apparatus 20 are provided at an upper portion of the region of the hot aisle in the container 10.

For the server 12, computers of various architectures (information processing apparatus) such as a Personal Computer (PC) server, a UNIX (registered trademark) server and a main frame are available. Further, the container 10 can incorporate not only the information processing apparatus such as a server 12 but also various electronic apparatus such as a storage apparatus for storing data of the information processing apparatus therein, a communication apparatus such as a switch or a rooter for connecting the information processing apparatus with a network and a power supply apparatus such as an Uninterruptible Power Supply (UPS). Such electronic apparatus as just described may be incorporated in the racks 11 or may be provided at an arbitrary position in the container 10. Further, for a housing of the servers 12, not only a rack mount type form but also various forms such as a tower type form and a blade type form may be used.

For simplified description, the embodiment is described below assuming that the container 10 includes a plurality of servers 12 provided as the electronic apparatus in the rack 11. It is to be noted that processing to be performed by the servers 12 or processing to be performed for the servers 12 in the following description can be applied similarly also to various electronic apparatus described above which the container 10 can include therein.

Further, for the data center 1, not only the container type data center 1 depicted in FIGS. 1 and 2 but also various data centers such as a modular type data center, a facility type data center such as a server rack data center including an air conditioning apparatus or an IDC data center and so forth are available.

Here, at least one of the plurality of servers 12 in the plurality of racks 11 depicted in FIGS. 1 and 2 functions as a management server 13 that controls the data center 1.

The management server (control apparatus) 13 is coupled with the air conditioning apparatus 20 and the servers 12 such that a signal can be transmitted to and received from them, and manages the servers 12 and controls the air conditioning apparatus 20. In particular, the management server 13 is coupled with each of the plurality of air conditioning apparatus 20 through a controlling line 1a, and performs control of the air conditioning apparatus 20 (cooling unit 21 and the fan 22) through the controlling line 1a. Further, the management server 13 is coupled with each of the servers 12 in the plurality of racks 11 (and electronic apparatus inside and outside of the racks 11) through a communication line 1b, and performs management of operation of the servers 12 and so forth and acquires various states of a heat generation amount, an internal temperature and so forth of the server 12 through the communication line 1b. It is to be noted that, for simplified description, part of the controlling lines 1a and the communication lines 1b is omitted in the example depicted in FIG. 1.

Details of the servers 12 (management server 13) are hereinafter described.

Each air conditioning apparatus 20 generates cooling wind to pass through (cool) the servers 12 in the racks 11 (and electronic apparatus inside and outside of the racks 11) of the container 10. Each of the plurality of air conditioning apparatus 20 includes a cooling unit 21 and one or more fans 22, and cools air taken in from the hot aisle through the duct 14 by the cooling unit 21 and sends cooled air as cooling wind (cold air) to the cold aisle by the fan 22. It is to be noted that each air conditioning apparatus 20 may include a cooling controlling unit (not depicted) that controls at least one of the cooling unit 21 and the fan 22.

The cooling unit 21 is an apparatus such as, for example, a heat exchanger, and the fan 22 is a facility fan that generates and sends air (air to pass through (cool) the servers 12) to the servers 12 through an opening. In FIGS. 1 and 2, in the container 10, the fans 22 are disposed, for example, in openings (not depicted) formed in a wall portion of the container 10 and are provided at positions generally opposed to the front face of the servers 12 in the racks 11. It is to be noted that the fan 22 may be further provided at a position at which an electronic apparatus provided at the outside of the rack 11 can be cooled.

### [1-2] Configuration of Server

Now, details of the servers 12 (management server 13) are described.

### [1-2-1] Hardware Configuration

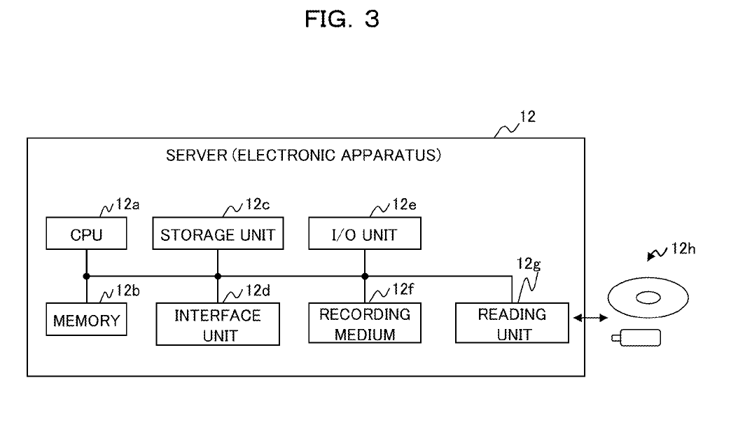

FIG. 3 is a block diagram depicting an example of a hardware configuration of the servers 12 depicted in FIG. 1.

As depicted in FIG. 3, each of the servers 12 including the management server 13 includes a Central Processing Unit (CPU) 12a, a memory 12b, a storage unit 12c, an interface unit 12d, an inputting and outputting unit 12e, a recording medium 12f and a reading unit 12g. It is to be noted that, since the plurality of servers 12 depicted in FIG. 1 can include hardware configurations similar to each other, the hardware configuration of the management server 13 is described below as a representative.

The CPU 12a is an arithmetic processing unit (processor) that is coupled with corresponding blocks 12b to 12g in FIG. 3 and performs various controls and arithmetic operations. The CPU 12a can implement various functions of the management server 13 by executing a program stored in the memory 12b, the storage unit 12c, the recording medium 12f or 12h, a Read Only Memory (ROM) not depicted or the like. It is to be noted that, as the processor, not only the CPU 12a but also an electronic circuit such as a Micro Processing Unit (MPU) may be used.

The memory 12b is a storage apparatus for storing various data, programs and so forth therein. The CPU 12a stores and develops data or a program into and in the memory 12b when the program is to be executed. It is to be noted that, for the memory 12b, a volatile memory such as, for example, a Random Access Memory (RAM) is available.

The storage unit 12c is hardware for storing various data, programs and so forth therein. For the storage unit 12c, various devices such as, for example, a magnetic disk apparatus such as a Hard Disk Drive (HDD), a semiconductor drive apparatus such as a Solid State Drive (SSD), a nonvolatile memory such as a flash memory and so forth are available.

The interface unit 12d controls coupling, communication and so forth with a network (not depicted) and the other servers 12 by wire link or wireless link. It is to be noted that the interface unit 12d can control also coupling and communication with the air conditioning apparatus 20 and the servers 12 coupled with the management server 13 through the controlling lines 1a and the communication lines 1b. For the interface unit 12d, for example, not only a Local Area Network (LAN), a fiber channel (Fibre Channel; FC) and so forth but also an adapter in compliance with Inter-Integrated Circuit (I2C) to be used for control of a peripheral equipment are available.

The inputting and outputting unit 12e can include at least one of an inputting apparatus such as a mouse or a keyboard and an outputting apparatus such as a display unit or a printer. For example, the inputting and outputting unit 12e is used for various works by a user, a manager or the like of the server 12 (management server 13).

The recording medium 12f is a storage device such as, for example, a flash memory or a ROM and can record various data or programs thereon. The reading unit 12g is an apparatus for reading out data or a program recorded on the (non-transitory) computer-readable recording medium 12h.

A control program for implementing functions of the management server 13 according to the embodiment may be stored on at least one of the recording media 12f and 12h. In particular, the CPU 12a can develop the control program read out from the recording medium 12f or the recording medium 12h through the reading unit 12g into a storage device such as the memory 12b and execute the control program. Consequently, the computer (including the CPU 12a, electronic apparatus, information processing apparatus, and various terminals) as the server 12 can implement the functions of the management server 13.

It is to be noted that, for the recording medium 12h, an optical disk such as, for example, a flexible disk, a Compact Disk (CD), a Digital Versatile Disk (DVD) or a Blu-ray disk and a flash memory such as a Universal Serial Bus (USB) memory or an SD card are available. It is to be noted that, as a CD, a CD-ROM, a CD-Recordable (CD-R), a CD-Rewritable (CD-RW) or the like is available. Further, as a DVD, a DVD-ROM, a DVD-RAM, a DVD-R, a DVD-RW, a DVD+R, a DVD+RW or the like is available.

It is to be noted that the blocks 12a to 12g described above are coupled for communication therebetween through a bus. Further, the hardware configuration described above of the server 12 (management server 13) is an exemplary configuration. In other words, increase or decrease (for example, omission of an arbitrary one or ones of the blocks 12a to 12g), division, integration by an arbitrary combination and so forth of the hardware in the server 12 may be suitably performed. Further, the configuration of the hardware of the server 12 used as the management server 13 and the configuration of the hardware of the other servers 12 may be different from each other. Also an electronic apparatus other than the server 12 may include at least part of the configuration depicted in FIG. 3.

### [1-2-2] Functional Configuration of the Management Server

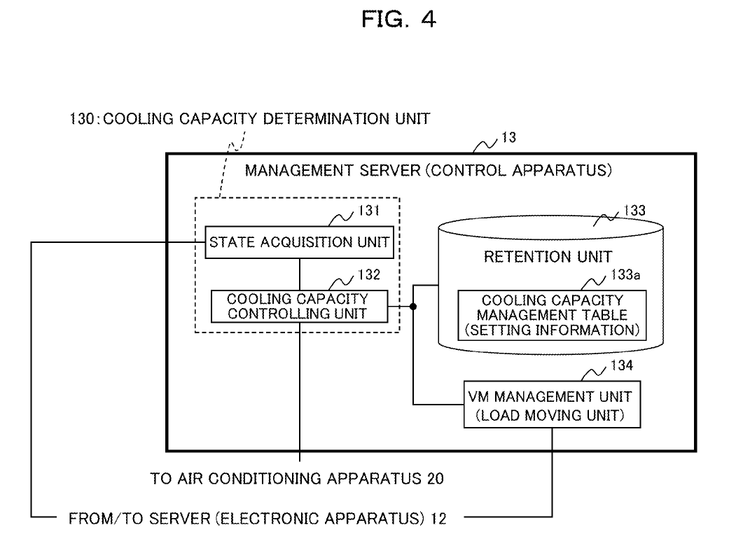

FIG. 4 is a view depicting an example of a functional configuration of the management server 13 depicted in FIG. 1.

Here, the installation number, individual cooling capacity and so forth of the air conditioning apparatus 20 are designed or selected in response to the number, power consumption, arrangement and so forth of electronic apparatus to be incorporated in the inside of the data center 1. In the data center 1 in which a plurality of air conditioning apparatus 20 designed or selected in such a manner as just described are provided, if some air conditioning apparatus 20 from among the plurality of air conditioning apparatus 20 are stopped by a failure or the like, then the remaining air conditioning apparatus 20 may difficult to cool all electronic apparatus sufficiently as described above. Accordingly, there is the possibility that the electronic apparatus may stop as described above.

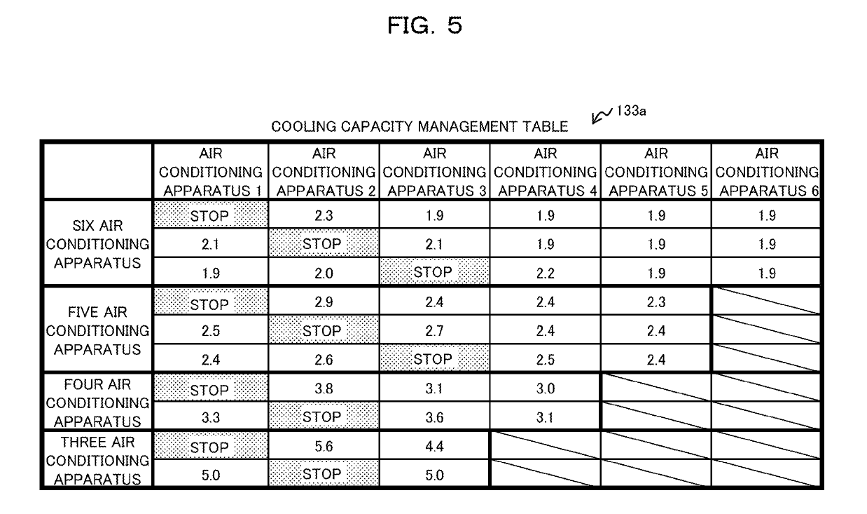

Therefore, the management server 13 controls the cooling capacity of each of the plurality of air conditioning apparatus 20 to allocate the cooling capacity of the stopping air conditioning apparatus (first air conditioning apparatus) 20 from among the plurality of air conditioning apparatus 20 to the operating (operative) air conditioning apparatus (second air conditioning apparatus) 20 other than the stopping air conditioning apparatus 20. At this time, the management server 13 performs the control just described based on a table (refer to FIG. 5) determined in advance. Consequently, since cooling for the servers 12 to be performed by the stopping air conditioning apparatus 20 can be performed in place by the other air conditioning apparatus 20, even if some air conditioning apparatus 20 fails, the processing of the servers 12 can be performed continuously.

It is to be noted that the cooling capacity is information (parameter) indicative of strength of cooling by the air conditioning apparatus 20 and determined based on the temperature difference between an intake air temperature and an exhaust air temperature to and from the cooling unit 21 of the air conditioning apparatus 20 and the airflow volume of the fan 22. For example, the cooling capacity has a value that increases in proportion to the product of the temperature difference and the airflow volume and can be represented in a unit of watt (W), namely, as power to be supplied to the air conditioning apparatus 20 (power consumption of the air conditioning apparatus 20). The management server 13 can control the cooling capacity of the air conditioning apparatus 20 by adjusting at least one of the airflow volume of and the temperature difference across the air conditioning apparatus 20.

For example, the management server 13 increases the temperature difference to enhance the cooling capacity by decreasing the setting temperature of the cooling unit 21 (increasing the supply power). On the other hand, the management server 13 decreases the temperature difference to lower the cooling capacity by raising the setting temperature of the cooling unit 21 (decreasing the power consumption). Further, the management server 13 increases the airflow volume and enhance the cooling capacity by increasing the power to be supplied to the fan 22 to increase the rotation speed of the fan 22. On the other hand, the management server 13 decreases the speed of rotation of the fan 22 to decrease the airflow volume by lowering the cooling capacity to decrease the power to be supplied to the fan 22.

It is to be noted that the management server 13 may directly control at least one of the cooling unit 21 and the fan 22 to vary the airflow volume of and the temperature difference across the air conditioning apparatus 20. Further, where the air conditioning apparatus 20 includes a cooling controlling unit for controlling at least one of the cooling unit 21 and the fan 22, the management server 13 may issue an instruction to control the airflow volume and the temperature difference to the cooling controlling unit through the controlling line 1a.

A configuration of the management server 13 is described below. As depicting in FIG. 4, the management server 13 includes a state acquisition unit 131, a cooling capacity controlling unit 132, a retention unit 133 and a Virtual Machine (VM) management unit 134.

The state acquisition unit 131 acquires state information relating to a state of the plurality of servers 12 (electronic apparatus) through the communication lines 1b. The state information includes a total heat generation amount (for example, power consumption) of the plurality of servers 12, a temperature of each server 12 (for example, an internal temperature such as a temperature of the CPU 12a) and so forth.

For example, the state acquisition unit 131 transmits an acquisition request for power consumption and a CPU temperature to each server 12 periodically or at a predetermined timing. Then, the state acquisition unit 131 receives an acquisition response including the power consumption and the CPU temperature acquired by a predetermined application or the like from the servers 12 to which the acquisition request has been transmitted. When the acquisition response is received, the state acquisition unit 131 issues a notification of the power consumption included in the acquisition response to the cooling capacity controlling unit 132. Further, the state acquisition unit 131 issues a notification of the CPU temperature included in the acquisition response to the VM management unit 134 in an associated relationship with the server 12. It is to be noted that the state acquisition unit 131 may further issue a notification of the CPU temperature to the cooling capacity controlling unit 132.

It is to be noted that the state acquisition unit 131 may transmit the acquisition request for the power consumption and the acquisition request for the CPU temperature to the server 12 separately at different timings from each other. Further, the state acquisition unit 131 may acquire an intake air/exhaust air temperature of each server 12, an operating ratio of each server 12 (for example, a CPU load factor) and so forth in place of or together with the CPU temperature such that the acquired information is issued as a notification to the VM management unit 134 (and the cooling capacity controlling unit 132).

Further, the state acquisition unit 131 detects through the controlling lines 1a that each of the plurality of air conditioning apparatus 20 is stopped by a failure or the like. The detection may be performed through periodical communication (heartbeat or the like) with the air conditioning apparatus 20 or may be performed by reception of a signal representative of stopping by a failure or the like from the air conditioning apparatus 20, and can be performed by various known methods. Therefore, detailed description of the detection is omitted herein. If it is detected that an air conditioning apparatus 20 is stopped, then the state acquisition unit 131 issues a notification of information of the stopping air conditioning apparatus 20 to the cooling capacity controlling unit 132.

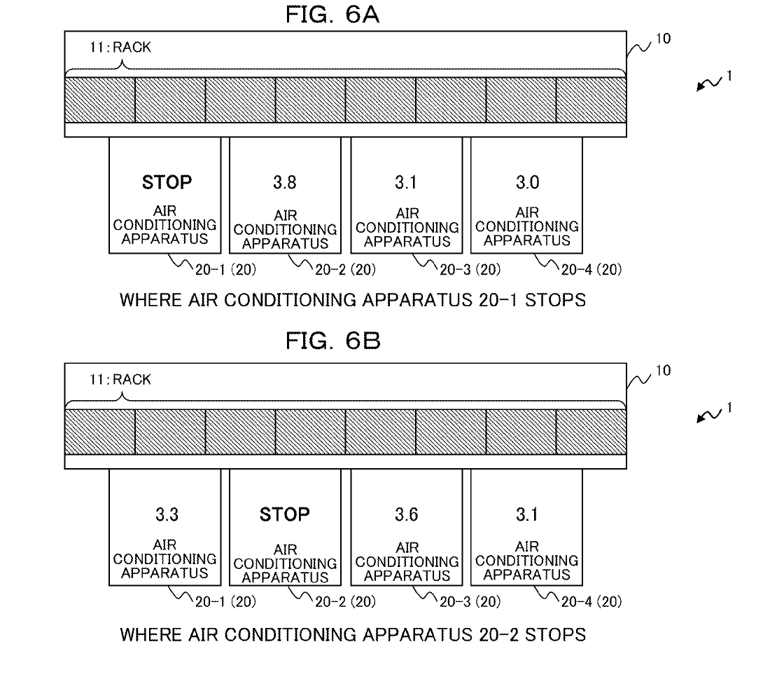

The retention unit 133 is a storage region for retaining a cooling capacity management table 133a therein and is implemented, for example, by the memory 12b described hereinabove. FIG. 5 is a view depicting an example of the cooling capacity management table 133a retained in the management server 13 depicted in FIG. 4, and FIGS. 6A and 6B are views individually illustrating the cooling capacity management table 133a.

As depicted in FIG. 5, the cooling capacity management table (setting information) 133a represents information indicative of a rate of the cooling capacity to be allocated to each of the operating air conditioning apparatus 20 in order to allocate the cooling capacity of the failing (stopping) air conditioning apparatus 20 to the individual operating air conditioning apparatus 20. In particular, the cooling capacity management table 133a includes a plurality of patterns (combinations) of the number (quantity) of the plurality of air conditioning apparatus and the installation position of the failing air conditioning apparatus 20, and a rate of the cooling capacity to be allocated (allocated) to each of the operating air conditioning apparatus 20 for each pattern is set.

For example, in FIG. 5, the cooling capacity management table 133a indicates rates of the cooling capacity in cases in which the number of air conditioning apparatus 20 is 6, 5, 4 and 3 (represented as “six air conditioning apparatus” to “three air conditioning apparatus”, respectively). Further, the cooling capacity management table 133a indicates a rate of the cooling capacity in each of a case in which the first air conditioning apparatus 20 from the left stops, another case in which the second air conditioning apparatus 20 from the left stops and a further case in which the third air conditioning apparatus 20 from the left stops (represented as “air conditioning apparatus 1” to “air conditioning apparatus 3”, respectively; “air conditioning apparatus 3” is applied only in a case in which the six air conditioning apparatus 20 or the five air conditioning apparatus 20 are involved) for each of the numbers of air conditioning apparatus 20. It is to be noted that, since the values set in the cooling capacity management table 133a depicted in FIG. 5 involve some error because the effective number of digits is decreased in calculation of the rates (ratio), they are set such that the sum total of the rates (ratio) is “10”.

Details of the cooling capacity management table 133a are described below with reference to FIGS. 6A and 6B. As depicted in FIG. 6A, in an entry of the first row of “four air conditioning apparatus” in FIG. 5, rates of the cooling capacity to be allocated to the operating air conditioning apparatus 20-2 to 20-4 when the air conditioning apparatus 20-1 at the left end (“air conditioning apparatus 1” of FIG. 5) from among the four air conditioning apparatus 20 fails are set. The rates (ratio) of the cooling capacity in this case are “3.8”, “3.1” and “3.0” in order of the air conditioning apparatus 20-2 to 20-4. Further, as depicted in FIG. 6B, in an entry of the second row of “four air conditioning apparatus” in FIG. 5, rates of the cooling capacity to be allocated to the operating air conditioning apparatus 20-1, 20-3 and 20-4 when the second air conditioning apparatus 20-1 from left (“air conditioning apparatus 2” of FIG. 5) fails are set. The rates (ratio) of the cooling capacity in this case are “3.3”, “3.6” and “3.1” in order of the air conditioning apparatus 20-1, 20-3 and 20-4.

It is to be noted that the cooling capacity management table 133a depicted in FIG. 5 indicates rates of the cooling capacity in a case in which the air conditioning apparatus 20 at the left side with respect to the center of the table (“air conditioning apparatus 1” to “air conditioning apparatus 3”) stop. For example, when the air conditioning apparatus 20 at the right side with respect to the center of the table (“air conditioning apparatus 4” to “air conditioning apparatus 6”) stop, the cooling capacity management table 133a may be applied in the mirror symmetry with respect to the center of the table.

The cooling capacity management table 133a is produced/updated by a user who uses the server 12, a manager of the data center 1 or the management server 13 or the like and is stored into the retention unit 133. As the timing of the production/updating of the cooling capacity management table 133a, a timing at which the data center 1 is constructed, another timing at which the number of racks 11 is increased or decreased or some rack 11 is moved, a further timing at which the installation situation of a server 12 in the rack 11 varies or the like is available.

Here, the cooling capacity management table 133a is produced by the user, the manager or the like, for example, based on at least one of kinds of information (parameters) given below.
Distance between the air conditioning apparatus 20 and the rack 11 (for example, “800 mm”)
Height of the rack 11 and the container 10 (for example, “rack 2220 mm, container 3000 mm”)
Capacity of the container 10 (for example, “height 3000 mm, width 2240 mm, length 5100 mm”)
Number of the racks 11 and number of the air conditioning apparatus 20 (for example, “eight racks, four air conditioning apparatus”)
Size and disposition of the opening (blowout opening for the fan 22) of the air conditioning apparatus 20 (for example, “size 960 mm×1520 mm, disposition; central portion of the opposing rack 11”)
Size of the hot air exhaust opening of the hot aisle (coupling location between the duct 14 and the hot aisle) (for example, “350 mm×1000 mm”)

It is to be noted that, where the data center 1 (electronic apparatus such as a server 12 or an air conditioning apparatus 20) or the like can acquire at least one of the parameters mentioned hereinabove by a detection function such as one of various sensors, the management server 13 itself may produce/update the cooling capacity management table 133a.

Upon normal operation in which a failure of the air conditioning apparatus 20 does not occur, the cooling capacity controlling unit 132 can determine the cooling capacity to be allocated to the plurality of air conditioning apparatus 20 using power consumption (total heat generation amount) of the plurality of servers 12 received in a notification from the state acquisition unit 131. Further, the cooling capacity controlling unit 132 can allocate the determined cooling capacities to the respective air conditioning apparatus 20.

Further, when a failure occurs in a first air conditioning apparatus 20 from among the plurality of air conditioning apparatus 20, the cooling capacity controlling unit 132 can determine the cooling capacity to be allocated to each of the second air conditioning apparatus 20 other than the first air conditioning apparatus 20 from among the plurality of air conditioning apparatus 20 based on the total heat generation amount described above. Further, the cooling capacity controlling unit 132 sets the determined cooling capacities to the respective second air conditioning apparatus 20. It is to be noted that the cooling capacity controlling unit 132 can detect a failure (stopping) of the first air conditioning apparatus 20 based on the notification issued from the state acquisition unit 131.

Here, when a failure occurs in a first air conditioning apparatus 20, the cooling capacity controlling unit 132 allocates the cooling capacity of the first air conditioning apparatus 20 to second air conditioning apparatus 20 based on the cooling capacity management table 133a determined in advance. In particular, the cooling capacity controlling unit 132 determines and allocates the cooling capacity to be allocated to each of the second air conditioning apparatus 20 based on the total heat generation amount such that the cooling capacity is allocated to the second air conditioning apparatus 20 in accordance with the rates of the cooling capacity indicated by the cooling capacity management table 133a.

In particular, the state acquisition unit 131 and the cooling capacity controlling unit 132 are an example of a cooling capacity determination unit 130 that acquires state information and determines the cooling capacity to be allocated to each of the second air conditioning apparatus 20 based on the total heat generation amount of the plurality of electronic apparatus 12 included in the acquired state information so as to allocate the cooling capacity to the second air conditioning apparatus 20 in accordance with the rates based on the setting information.

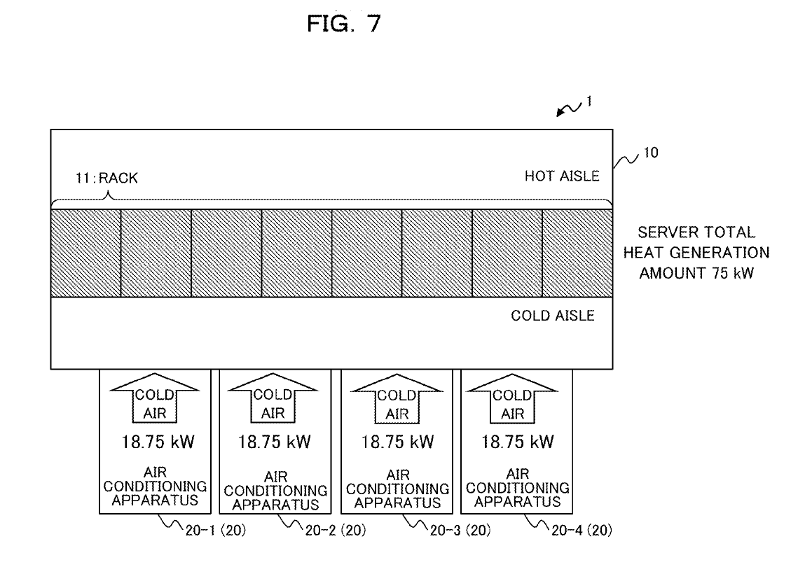

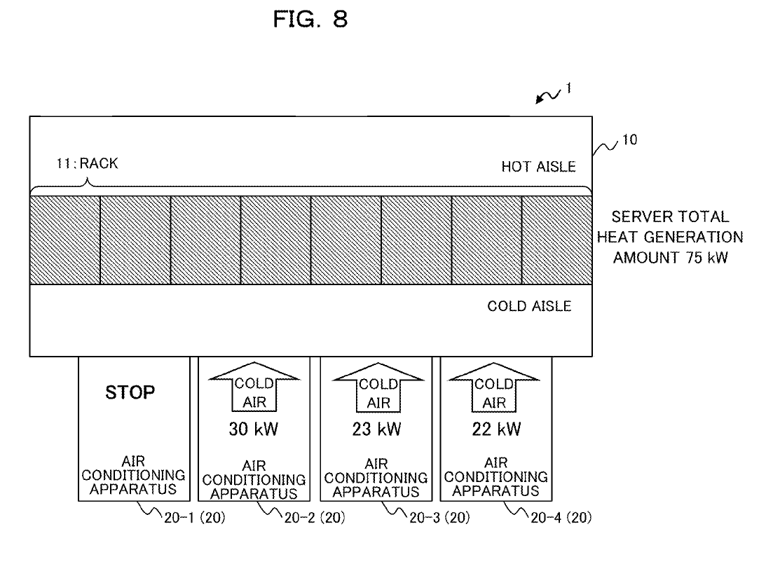

Processing of the cooling capacity controlling unit 132 is described below with reference to FIGS. 7 and 8. FIGS. 7 and 8 are views individually depicting an example of the cooling capacity to be allocated to the plurality of air conditioning apparatus 20 depicted in FIG. 2. It is to be noted that, in FIGS. 7 and 8, it is assumed that the total heat generation amount (total power consumption) of all servers 12 (electronic apparatus) incorporated in the plurality of racks 11 is 75 kW. In this case, the cooling capacity controlling unit 132 receives a notification of the total heat generation amount of 75 kW as the power consumption of the plurality of servers 12 from the state acquisition unit 131.

As depicted in FIG. 7, upon normal operation of the air conditioning apparatus 20, the cooling capacity controlling unit 132 determines a cooling capacity of 18.75 kW calculated by dividing the power consumption of 75 kW, for example, by 4 which is the number of air conditioning apparatus 20 as the cooling capacity to be allocated to each of the plurality of air conditioning apparatus 20. Then, the cooling capacity controlling unit 132 allocates the determined cooling capacity equally to the air conditioning apparatus 20-1 to 20-4.

On the other hand, when the air conditioning apparatus 20-1 fails, the cooling capacity controlling unit 132 determines an entry of the cooling capacity management table 133a to be applied in response to the number of air conditioning apparatus 20 and a relationship between the installation positions of the first air conditioning apparatus 20 and each of the second air conditioning apparatus 20 in the plurality of air conditioning apparatus 20. It is to be noted that, in the example of FIG. 8, the entry of the first row of “4 air conditioning apparatus” of FIG. 5 is applied. Then, the cooling capacity controlling unit 132 obtains 30 kW, 23 kW and 22 kW corresponding to the ratio of “3.8:3.1:3.0” with respect to the total heat generation amount of 75 kW as the cooling capacity to be allocated to the three air conditioning apparatus 20-2 to 20-4. Then, the cooling capacity controlling unit 132 allocates the determined cooling capacities to the air conditioning apparatus 20-2 to 20-4.

In this manner, when a failure of an air conditioning apparatus 20 occurs, the management server 13 can allocate the cooling capacity to the operating air conditioning apparatus 20 with rates based on the cooling capacity management table 133a. Accordingly, also when an air conditioning apparatus 20 fails, the servers 12 can be operated similarly as upon normal operation while minimum (optimum) power is supplied to the air conditioning apparatus 20. Further, the management server 13 determines cooling capacities to be allocated to the operating air conditioning apparatus 20 based on the cooling capacity management table 133a determined in advance. Consequently, the cooling capacity can be allocated to the air conditioning apparatus 20 quickly in comparison with an alternative case in which the cooling capacity is determined using temperature detection by a sensor or the like upon failure of an air conditioning apparatus 20.

Further, the cooling capacity controlling unit 132 allocates the total heat generation amount (reference cooling capacity for cancelling the total heat generation amount (for sufficient cooling)) of the servers 12 as cooling capacities of the respective operating air conditioning apparatus 20 in accordance with the ratio of the cooling capacity management table 133a in accordance with a failure position. In other words, the plurality of servers 12 can be cooled if the sum total of the cooling capacity of the operating air conditioning apparatus 20 is equal to or higher than the reference cooling capacity.

However, in a case of such a structure that the electronic apparatus and the air conditioning apparatus 20 are disposed in a substantially opposing relationship to each other in a small space as in the container type data center 1 (refer to FIG. 2), it is sometimes difficult to cool the electronic apparatus opposing to the stopping air conditioning apparatus 20 using some other air conditioning apparatus 20. Therefore, the cooling capacity management table 133a is set such that the rate of the cooling capacity to be allocated to the operating air conditioning apparatus 20 increases as the installation position of the operating air conditioning apparatus 20 is positioned nearer to that of the failing air conditioning apparatus 20 from among the plurality of air conditioning apparatus 20. Further, when an air conditioning apparatus 20 stops, the cooling capacity controlling unit 132 allocates the cooling capacity to the operating air conditioning apparatus 20 such that the cooling capacity is at least equal to or higher than the reference cooling capacity by all of the operating air conditioning apparatus 20. Consequently, since each operating air conditioning apparatus 20 performs cooling with a higher cooling capacity as the air conditioning apparatus 20 is positioned nearer to the stopping air conditioning apparatus 20, also the electronic apparatus substantially opposed to the stopping air conditioning apparatus 20 can be cooled efficiently with minimum power consumption.

Further, since the minimum cooling capacity (reference cooling capacity) can be grasped in advance by the state acquisition unit 131, the user, the manager or the like can install the air conditioning apparatus 20 with minimum redundancy.

It is to be noted that the cooling capacity controlling unit 132 may determine, after the cooling capacity is allocated to the operating air conditioning apparatus 20, whether or not the CPU temperature of each of the plurality of air conditioning apparatus 20 (temperature of each server 12) received as a notification from the state acquisition unit 131 is higher than a predetermined value. When there is a server 12 whose CPU temperature is higher than the predetermined value, the cooling capacity controlling unit 132 may allocate the cooling capacity to the operating air conditioning apparatus 20 again such that the cooling capacity of the operating air conditioning apparatus 20 installed at a position near to the server 12 is increased by a predetermined amount. It is to be noted that the predetermined value is a reference value for determining whether or not the cooling of the server is insufficient. For example, where the state information received as a notification from the state acquisition unit 131 is the CPU temperature (or intake air/exhaust air temperature, CPU load or the like of each server 12), the predetermined value is a threshold value for determining that the CPU 12a is in an overheated state.

In this manner, after the cooling capacity is allocated to the operating air conditioning apparatus 20, the cooling capacity controlling unit 132 can adjust the cooling capacities allocated to the individual operating air conditioning apparatus 20 based on the installation position of the server 12 whose temperature is higher than a predetermined value. It is to be noted that the cooling capacity controlling unit 132 can perform the adjustment of the cooling capacity described above also after load movement between the servers 12 by the VM management unit 134 hereinafter described. Consequently, the management server 13 can flexibly cope also with an actual heat generation state of the electronic apparatus such as a load on those servers 12 which is difficult to fully follow up by the control based on the rates of the cooling capacity management table 133a, disposition of the servers 12 in the rack 11 or the like, and the electronic apparatus can be cooled with certainty. It is to be noted that the adjustment of the cooling capacity by the cooling capacity controlling unit 132 may be performed after the cooling capacity is allocated equally to the air conditioning apparatus 20 upon normal operation of the air conditioning apparatus 20.

Further, since the rates depicted in FIG. 5 are calculated in advance and set in the cooling capacity management table 133a, where a predetermined number of (in FIG. 5, six) air conditioning apparatus 20 are installed in the data center 1, the cooling capacity controlling unit 132 can use the rates depicted in FIG. 5 as they are. On the other hand, when the number of air conditioning apparatus 20 is greater than the predetermined number, the cooling capacity controlling unit 132 can determine the cooling capacity, for example, by any of methods described below.
The cooling capacity of an air conditioning apparatus 20 nearest to the stopping air conditioning apparatus 20 is set higher by a predetermined rate (for example, by approximately 10%) in comparison with the cooling capacity of the other air conditioning apparatus 20 while substantially equal cooling capacities to each other are allocated to the other air conditioning apparatus 20.
The rates in the cooling capacity management table 133a in the case in which the number of the air conditioning apparatus 20 is the predetermined number are converted into rates in the case in which the number of air conditioning apparatus 20 is an actual number, and the converted rates are used.

Consequently, in the cooling capacity management table 133a, the setting of all combinations between the number of air conditioning apparatus 20 incorporated in the data center 1 and the disposing position of the failing air conditioning apparatus 20 may be omitted. Therefore, the use amount of the memory 12b of the management server 13 can be suppressed.

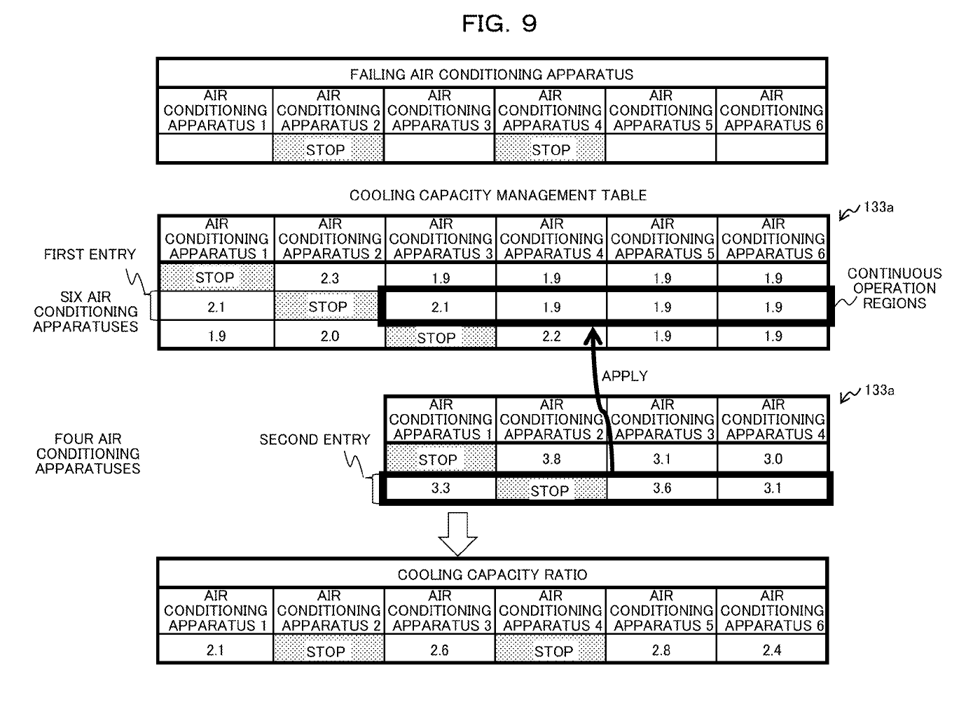

It is to be noted that the cooling capacity management table 133a indicates cooling capacities in the case in which the number of failing air conditioning apparatus 20 is one as depicted in FIG. 5. However, also when a plural number of air conditioning apparatus 20 from among the plurality of air conditioning apparatus 20 fail, the management server 13 can allocate the cooling capacity to the operating air conditioning apparatus 20 based on the cooling capacity management table 133a. FIG. 9 is a view illustrating a method of allocating the cooling capacity to the air conditioning apparatus 20 when a plural number of (for example, two) air conditioning apparatus 20 depicted in FIG. 2 fail.

When a plural number of air conditioning apparatus 20 fail, the cooling capacity controlling unit 132 can allocate the cooling capacity of the failing air conditioning apparatus 20 to the operating air conditioning apparatus 20 by combining entries of the cooling capacity management table 133a.

For example, when the second and fourth air conditioning apparatus 20 from the left (“air conditioning apparatus 2” and “air conditioning apparatus 4”) from among the six air conditioning apparatus 20 fail as depicted in FIG. 9, the cooling capacity controlling unit 132 specifies the first air conditioning apparatus 20 at the installation position near to one of the left end and the right end in the arrangement of the air conditioning apparatus 20. In the example of FIG. 9, the “air conditioning apparatus 2” second from the left is specified.

Then, the cooling capacity controlling unit 132 refers to a plurality of entries of “six air conditioning apparatus” of the cooling capacity management table 133a which correspond to the total number of the air conditioning apparatus 20. Then, the cooling capacity controlling unit 132 specifies, from among the plurality of entries of “six air conditioning apparatus”, an entry (first entry) in which the position of the stopping air conditioning apparatus 20 corresponds to the position of the specified first air conditioning apparatus 20. In the example of FIG. 9, the entry (first entry) when the “air conditioning apparatus 2” from among the “six air conditioning apparatus” in the cooling capacity management table 133a stops is specified.

Further, the cooling capacity controlling unit 132 acquires a region (successive operation region) in which the air conditioning apparatus 20 adjacent to each other successively operate and the number of such adjacent air conditioning apparatus in the specified first entry. In the example of FIG. 9, the region from “air conditioning apparatus 3” to “air conditioning apparatus 6” in the first entry is the successive operation region and the number of air conditioning apparatus 20 in the region is four.

Then, the cooling capacity controlling unit 132 refers to a plurality of entries of “four air conditioning apparatus” of the cooling capacity management table 133a corresponding to the number of the air conditioning apparatus 20 in the specified successive operation region. Then, the cooling capacity controlling unit 132 specifies, from among the plurality of entries of “four air conditioning apparatus”, an entry (second entry) in which the position of the stopping air conditioning apparatus 20 corresponds to the position of the “air conditioning apparatus 4” when the entry is applied to the successive operation region of the entry 1. In the example of FIG. 9, the entry (second entry) when the “air conditioning apparatus 2” from among the “four air conditioning apparatus” in the cooling capacity management table 133a stops is specified.

Finally, the cooling capacity controlling unit 132 applies the second entry to the successive operation region of the first entry to calculate rates of the operating air conditioning apparatus 20 (“air conditioning apparatus 3”, “air conditioning apparatus 5” and “air conditioning apparatus 6” in the first entry) in the successive operation region. For example, the cooling capacity controlling unit 132 can calculate the ratio of the cooling capacity by dividing the total value of the rates in the successive operation region of the first entry by the total value of the rates in the first entry and then multiplying the result of the division by the rates of the air conditioning apparatus 20 in the second entry to be applied to the successive operation region.

In the example of FIG. 9, the cooling capacity controlling unit 132 divides the total value (“2.1”+“1.9”+“1.9”+“1.9”=“7.8”) of the rates in the successive operation region by the total value (“2.1”+“7.8”=“9.9”) of the rates in the first entry and obtains “0.78” as a result of the division. Then, the cooling capacity controlling unit 132 multiplies the division result “0.78” by the rates (“3.3”, “3.6”, “3.1”) of the air conditioning apparatus 20 in the second entry to be applied to the “air conditioning apparatus 3”, “air conditioning apparatus 5” and “air conditioning apparatus 6” in the successive operation region. Consequently, the cooling capacity controlling unit 132 can calculate “2.6”, “2.8” and “3.4” as the rates (ratio of the cooling capacity) of the “air conditioning apparatus 3”, “air conditioning apparatus 5” and “air conditioning apparatus 6” in the successive operation region. It is to be noted that, since an error is involved in the values of the cooling capacity management table 133a and the table depicted in FIG. 9 as described above, some error (variation) is involved also in the result of the calculation described above.

In this manner, the cooling capacity controlling unit 132 can continue the processing of the server 12 also when a plurality of first air conditioning apparatus 20 fail. In particular, the cooling capacity controlling unit 132 can determine the rates of the cooling capacity to be allocated to the second air conditioning apparatus 20 based on two or more combinations in the cooling capacity management table 133a corresponding to the relationship of the installation positions of the plurality of first air conditioning apparatus 20 and the plurality of second air conditioning apparatus 20. Consequently, the management server 13 can perform allocation of the cooling capacity in accordance with an arbitrary number of air conditioning apparatus and an arbitrary number of failing air conditioning apparatus irrespective of setting contents of the cooling capacity management table 133a.

It is to be noted that, while an example in which the rates of two entries of the cooling capacity management table 133a are mixed when two air conditioning apparatus 20 fail is depicted in FIG. 9, the mixture is not limited to this. The cooling capacity controlling unit 132 can also mix rates of three or more entries of the cooling capacity management table 133a in response to the number of failing air conditioning apparatus 20. It is to be noted that, since a technique for mixing rates of three or more entries can be implemented by a method of mixing rates of a third entry with a result of mixture of the rates of two entries, detailed description of the technique is omitted herein.

The control by the management server 13 described above can be performed similarly also for an electronic apparatus provided outside the rack 11 and an air conditioning apparatus 20 corresponding to the electronic apparatus.

Now, the VM management unit 134 is described.

In the virtualization technology for causing a plurality of servers to execute a VM, power consumption of a plurality of servers can be decreased by moving a load on some specific server among the plurality of servers and placing the server having no load into an idling or stopping state.

The description is given assuming that each of the plurality of servers 12 in the embodiment executes the VM described above.

The VM management unit (load moving unit) 134 has a load movement function for moving a load of the VM or the like to be executed by a server 12 to a different server 12.

In particular, the VM management unit 134 determines whether or not the CPU temperature (temperature of the server 12) of each of the plurality of servers 12 received as a notification from the state acquisition unit 131 is higher than the predetermined value. When a server 12 (first server 12; first electronic apparatus) whose CPU temperature is higher than the predetermined value exists, the VM management unit 134 causes a second server 12 (second electronic apparatus 12) different from the first server 12 from among the plurality of servers 12 to execute a process to be executed by the first server 12. Preferably, the second server 12 here is one of the servers 12 which opposes to an air conditioning apparatus 20 that has a sufficient cooling capacity. It is to be noted that the VM management unit 134 performs the movement of the load on the server 12 through the communication line 1b.

The VM management unit 134 may execute the movement of the load on the server 12 just described upon normal operation of the air conditioning apparatus 20 or when the air conditioning apparatus 20 stops.

For example, the VM management unit 134 may execute the movement of the load on the server 12 described above based on the state information received as a notification from the state acquisition unit 131 after allocation of the cooling capacity based on the rates of the cooling capacity management table 133a is performed by the cooling capacity controlling unit 132.

In particular, when an air conditioning apparatus 20 fails, the management server 13 first performs control of allocation of the cooling capacity on the operating air conditioning apparatus 20 by the cooling capacity controlling unit 132 as described above. Then, when the CPU temperature of the first server 12 is higher than a prescribed value, the management server 13 moves the load on the certain first server 12 to a second server 12 spaced away from the stopping air conditioning apparatus 20.

It is to be noted that time is sometimes taken for the movement of the load on the server 12 depending upon the state of a network. Further, by moving the load on a server 12, power of the certain server 12 is consumed more and the server 12 generates heat more. However, as described above, when an air conditioning apparatus 20 fails, the management server 13 can perform the control for the air conditioning apparatus 20 first and then integrally control the cooling capacity (facility) of the air conditioning apparatus 20 and the load on the server 12 using the movement of the load on the server 12 as next means. By the control, heat generation of the server 12 by the movement of the load on the server 12 can be suppressed. Further, since the VM management unit 134 performs communication with the servers 12 through the communication lines 1b, a network for load movement need not be used. Accordingly, the server 12 can be operated continuously without decreasing the processing speed of the server 12 in comparison with that upon normal operation.

As described above, with the management server 13 according to the embodiment, in the data center 1 in which a plurality of air conditioning apparatus 20 individually corresponding to a plurality of electronic apparatus are provided, the processing of the electronic apparatus can be continued also when an air conditioning apparatus 20 stops.

Incidentally, the data center 1 can incorporate a greater number of air conditioning apparatus 20 than that by which all electronic apparatus can be cooled sufficiently upon normal operation of the electronic apparatus so as to provide redundancy. However, by operating those air conditioning apparatus 20 which are originally unnecessary, the air conditioning apparatus 20 excessively cool the inside of the data center 1 and consume surplus power. Also in such a case as just described, upon normal operation of the air conditioning apparatus 20, the management server 13 can supply minimum power to the air conditioning apparatus 20 by receiving the total heat generation amount of the servers and controlling the cooling capacity of the air conditioning apparatus 20. In other words, with the management server 13 according to the embodiment, the air conditioning apparatus 20 can be operated with minimum power consumption while the redundancy of the air conditioning apparatus 20 is maintained.

### [1-3] Example of Operation

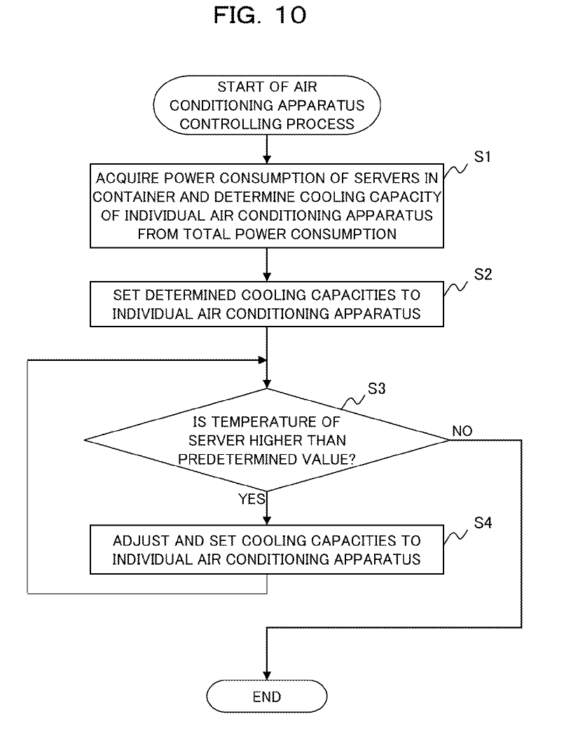

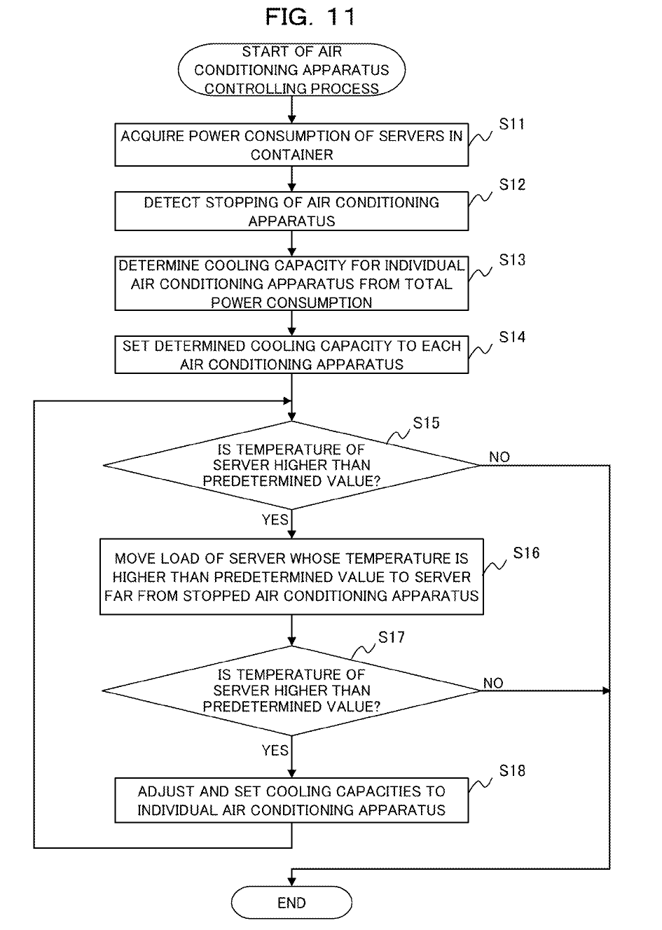

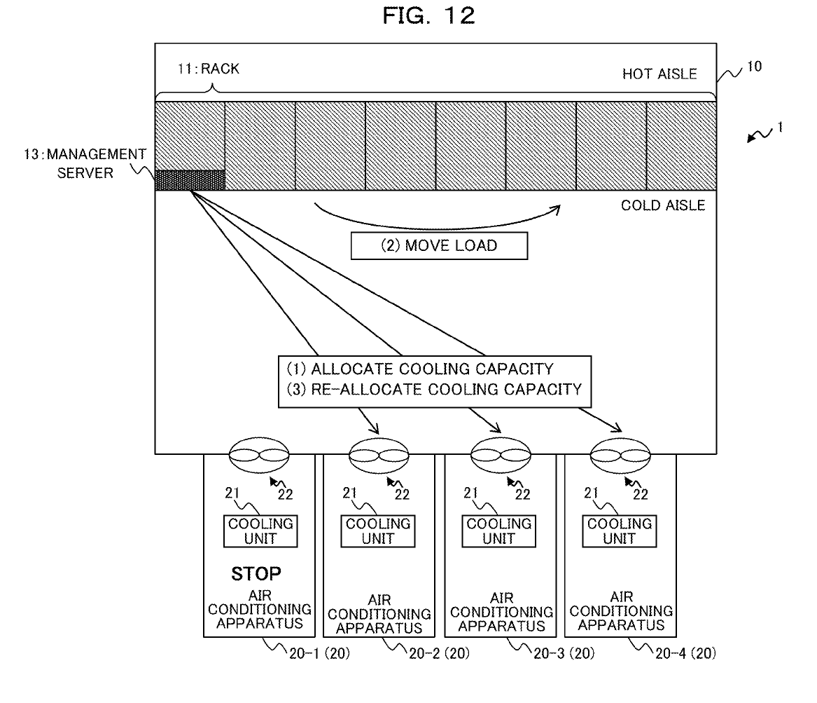

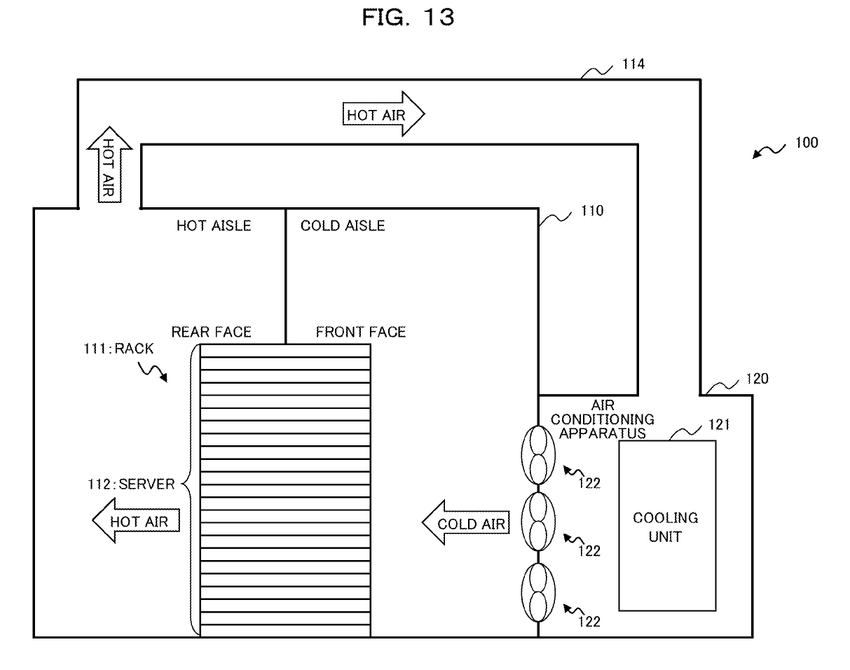

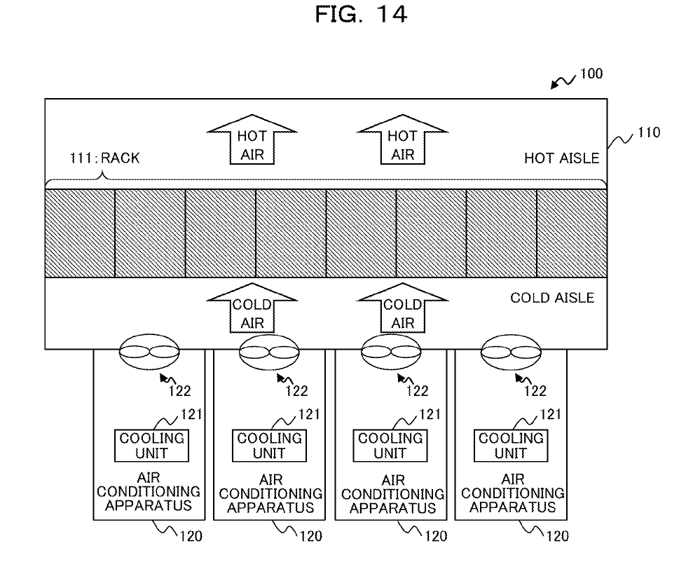

Now, control of the air conditioning apparatus 20 in the data center 1 as an example of the embodiment configured in such a manner as described above is described with reference to FIGS. 10 to 12. FIGS. 10 and 11 are flowcharts illustrating examples of a controlling process for the air conditioning apparatus 20 in the data center 1 depicted in FIG. 1. FIG. 12 is a view illustrating a processing procedure by the management server 13 depicted in FIG. 4 when an air conditioning apparatus 20 stops.

First, a process of the management server 13 upon normal operation of the air conditioning apparatus 20 is described with reference to FIG. 10.

As depicted in FIG. 10, by the state acquisition unit 131, state information (for example, power consumption) of the servers 12 in the container 10 is acquired through the communication lines 1b, and, by the cooling capacity controlling unit 132, the cooling capacity of the individual air conditioning apparatus 20 is determined based on the total power consumption (step S1). It is to be noted that, at step S1, the cooling capacity controlling unit 132 divides the total power consumption by the number of the plurality of air conditioning apparatus 20 to calculate the cooling capacity. Then, by the cooling capacity controlling unit 132, the determined cooling capacity is set to each of the air conditioning apparatus 20 (step S2).

Then, by the state acquisition unit 131, state information (for example, the CPU temperature) of the servers 12 of the container 10 is acquired through the communication lines 1b and, by the cooling capacity controlling unit 132, it is determined whether or not the temperature (CPU temperature) of some of the servers 12 is higher than the predetermined value (step S3). When there is no server 12 whose CPU temperature is higher than the predetermined value (No route at step S3), the processing by the management server 13 ends.

On the other hand, when the server 12 whose CPU temperature is higher than the predetermined value exists (Yes route at step S3), by the cooling capacity controlling unit 132, the cooling capacity of the air conditioning apparatus 20 opposing to (or in the proximity of) the server 12 is adjusted (increased). Then, by the cooling capacity controlling unit 132, the cooling capacity re-allocated based on a result of the adjustment is set to the plurality of air conditioning apparatus 20 (step S4), whereafter the processing advances to step S3. It is to be noted that the processes at steps S3 and S4 are repetitively executed until it is determined at step S3 that there is no server 12 whose CPU temperature is higher than the predetermined value.

Now, a process of the management server 13 when an air conditioning apparatus 20 fails is described with reference to FIGS. 11 and 12.

As depicted in FIG. 11, by the state acquisition unit 131, state information (for example, power consumption) of the servers 12 in the container 10 is acquired through the communication lines 1b (step S11). Further, by the state acquisition unit 131, a failure of an air conditioning apparatus 20 is detected (step S12).

Then, by the cooling capacity controlling unit 132, the cooling capacities of the individual air conditioning apparatus 20 during operation are determined from the total power consumption (step S13). It is to be noted that, at step S13, the cooling capacity controlling unit 132 determines the cooling capacity of the stopping air conditioning apparatus 20 to be allocated to the operating air conditioning apparatus 20 based on the total power consumption and the rates in the cooling capacity management table 133a. Then, the cooling capacities determined by the cooling capacity controlling unit 132 are set to the individual air conditioning apparatus 20 (step S14; refer to (1) of FIG. 12).

Then, by the cooling capacity controlling unit 132, state information (for example, the CPU temperature) of the servers in the container 10 is acquired through the communication lines 1b and, by the VM management unit 134, it is determined whether or not the temperature (CPU temperature) of some of the servers 12 is higher than the predetermined value (step S15). When there is no server whose CPU temperature is higher than the predetermined value (No route at step S15), the processing by the management server 13 ends.

On the other hand, when a server 12 whose CPU temperature is higher than the predetermined value exists (Yes route at step S15), by the VM management unit 134, the load to be executed by the server 12 is moved to a server spaced far away from the stopping air conditioning apparatus 20 (step S16; refer to (2) of FIG. 12). Then, the processing advances to step S17.

At step S17, by the state acquisition unit 131, state information (for example, the CPU temperature) of the servers 12 in the container 10 is acquired through the communication lines 1b and, by the cooling capacity controlling unit 132, it is determined whether or not the temperature (CPU temperature) of some of the servers 12 is higher than the predetermined value. When there is no server 12 whose CPU temperature is higher than the predetermined value (No route at step S17), the processing by the management server 13 ends.

On the other hand, when a server 12 whose CPU temperature is higher than the predetermined value exists (Yes route at step S17), by the cooling capacity controlling unit 132, the cooling capacity of an air conditioning apparatus 20 opposing to (or in the proximity of) the server 12 is adjusted (increased). Then, by the cooling capacity controlling unit 132, the cooling capacities re-allocated based on a result of the adjustment are set to the plurality of air conditioning apparatus 20 (step S18; refer to (3) of FIG. 12), whereafter the processing advances to step S15. It is to be noted that the processes at steps S15 and S18 are repetitively executed until it is determined at step S15 or 17 that there is no server 12 whose CPU temperature is higher than the predetermined value.

The controlling process by the air conditioning apparatus 20 in the data center 1 according to the embodiment ends therewith.

It is to be noted that the management server 13 can execute the controlling process for the air conditioning apparatus 20 depicted in FIGS. 10 and 11 periodically or at a predetermined timing.

Further, the execution order of steps S11 and S12 of FIG. 11 may be reversed. Further, the processes at steps S15 and S16 may be omitted. Further, after completion of the process at step S18, the processing may be advanced not to step S15 but to step S17.

Further, the execution order of steps S15 and S16 and steps S17 and S18 may be reversed. In this case, after completion of the process at step S16, the processing may advance not to step S17 but to step S15.

### [2] Others

While the preferred embodiment of the present invention is described in detail above, the present invention is not limited to the embodiment specifically described above, and variations and modifications can be made without departing from the scope of the present invention.

For example, while it is described that at least one of the servers 12 is used as the management server 13 in the embodiment, the management server 13 is not limited to this. For example, an information processing apparatus (control apparatus) including a function as the management server 13 may be provided in the container 10 independently of the servers 12. Also in this case, the information processing apparatus is coupled with the electronic apparatus including the servers 12 and the plurality of air conditioning apparatus 20 through the controlling lines 1a and the communication lines 1b. It is to be noted that the information processing apparatus includes a processor such as a CPU and implements a function as the management server 13 by execution of the controlling program by the processor.

Consequently, part of the servers 12 to be used by the user does not have to be used as the management server 13, and the use efficiency of the servers 12 can be raised. Further, an operator who performs operation/management of the data center 1 need not construct the management server 13 utilizing a server 12 used by a user, and the workability or the maintainability is enhanced. Further, since the information processing apparatus having a function as the management server 13 can be incorporated in the container 10 in advance, the convenience to both of the user and the operator can be enhanced rather than those in an alternative case in which the management server 13 is constructed upon service providing of the data center 1.

Further, while it is described that the container type data center 1 depicted in FIG. 1 includes the duct 14 and each air conditioning apparatus 20 includes a cooling unit 21 so that cooling wind is circulated, the countermeasure for cooling wind is not limited to this. For example, each air conditioning apparatus 20 may include an opening for taking in external air from the outside therethrough such that airflow taken in through the opening from the outside is introduced as cooling wind to the cold aisle of the container 10. In this case, the container 10 can include, in the hot aisle, an opening for exhausting exhaust air (hot air) from the electronic apparatus such as the servers 12 to the outside of the container 10 therethrough.

Furthermore, the management server 13 may omit the VM management unit 134.

Further, while it is described that, in the cooling capacity management table 133a, one entry is set for a combination of the number of air conditioning apparatus 20 and the installation position of a failing air conditioning apparatus 20, setting of an entry is not limited to this. For example, in the cooling capacity management table 133a, a plurality of entries having the same combination of the number of air conditioning apparatus 20 and the installation position of a failing air conditioning apparatus 20 may be provided and besides ratios different among the plurality of entries may be set. In this case, the control of the air conditioning apparatus 20 by the management server 13 is performed, for example, in the following manner.

First, the cooling capacity controlling unit 132 performs the control of allocation of the cooling capacity as described above to the operating air conditioning apparatus 20. Then, when the CPU temperature of the first server 12 is higher than the predetermined value, the cooling capacity controlling unit 132 performs allocation of the cooling capacity to the air conditioning apparatus 20 using rates set in an entry different from the entry used first (previously). In this manner, by providing plurality of entries having rates different from each other, when the CPU temperature of the first server 12 is higher than the predetermined value, increase of the processing load on the server 12 can be suppressed rather than the processing load by the movement of the load on the server 12 by the VM management unit 134 and the cooling capacity can be improved at a high speed.

With the embodiment, in a data center in which a plurality of air conditioning apparatus individually corresponding to a plurality of electronic apparatus are provided, processing of the electronic apparatus can be continued even when some air conditioning apparatus stops.

All examples and conditional language recited herein are intended for the pedagogical purposes of aiding the reader in understanding the invention and the concepts contributed by the inventor to further the art, and are not to be construed limitations to such specifically recited examples and conditions, nor does the organization of such examples in the specification relate to a showing of the superiority and inferiority of the invention. Although one or more embodiments of the present inventions have been described in detail, it should be understood that the various changes, substitutions, and alterations could be made hereto without departing from the spirit and scope of the invention.

What is claimed is:

1. A data center, comprising:
a plurality of electronic apparatus;
a plurality of air conditioning apparatus individually corresponding to the plurality of electronic apparatus; and
a control apparatus that controls the plurality of air conditioning apparatus; wherein
the control apparatus includes a processor;
the processor
controls a cooling capacity of each of the plurality of air conditioning apparatus; and
when a failure occurs in a first air conditioning apparatus from among the plurality of air conditioning apparatus, allocates a cooling capacity of the first air conditioning apparatus to a second air conditioning apparatus from among the plurality of air conditioning apparatus based on setting information determined in advance.

2. The data center according to claim 1, wherein
the setting information indicates rates of the cooling capacity with which the cooling capacity of the first air conditioning apparatus is to be allocated to the second air conditioning apparatus; and
the processor allocates the cooling capacity to the second air conditioning apparatus with the rates of the cooling capacity indicated by the setting information.

3. The data center according to claim 2, wherein the setting information is set such that the rate of the cooling capacity to be allocated to the second air conditioning apparatus increases as an installation position of the second air conditioning apparatus from among the plurality of air conditioning apparatus comes near to that of the first air conditioning apparatus.

4. The data center according to claim 2, wherein
the setting information includes a plurality of combinations of a number of the plurality of air conditioning apparatus and an installation position of the first air conditioning apparatus and a rate of the cooling capacity to be allocated to each of the second air conditioning apparatus is set for each of the combinations; and
when a failure occurs in a plurality of first air conditioning apparatus from among the plurality of air conditioning apparatus, the processor determines a rate of the cooling capacity to be allocated to each of the second air conditioning apparatus based on two or more of the combinations in the setting information corresponding to a relationship of the installation positions between each of the first air conditioning apparatus and each of the second air conditioning apparatus from among the plurality of air conditioning apparatus.

5. The data center according to claim 2, wherein the processor acquires state information relating to a state of the plurality of electronic apparatus from the plurality of electronic apparatus, and determines the cooling capacity to be allocated to each of the second air conditioning apparatus based on a total heat generation amount of the plurality of electronic apparatus included in the acquired state information to allocate the cooling capacity to the second air conditioning apparatus with the rates based on the setting information.

6. The data center according to claim 5, wherein, when the processor determines, from temperatures of the plurality of electronic apparatus included in the state information, that the temperature of one of the plurality of electronic apparatus is higher than a predetermined value after the cooling capacity is allocated to the second air conditioning apparatus, the processor adjusts the cooling capacity allocated to the second air conditioning apparatus based on the installation position of the electronic apparatus whose temperature is higher than the predetermined value.

7. The data center according to claim 5, wherein, when the temperature of the first electronic apparatus from among the plurality of electronic apparatus is higher than a predetermined value from the temperatures of the plurality of electronic apparatus included in the state information, the processor causes the second electronic apparatus from among the plurality of electronic apparatus to execute a process to be executed by the first electronic apparatus.

8. A computer-readable recording medium having stored therein a controlling program for causing a control apparatus to execute a process for controlling a data center that includes a plurality of electronic apparatus and a plurality of air conditioning apparatus individually corresponding to the plurality of electronic apparatus, the process comprising:
controlling a cooling capacity of each of the plurality of air conditioning apparatus; and
allocating, when a failure occurs in a first air conditioning apparatus from among the plurality of air conditioning apparatus, the cooling capacity of the first air conditioning apparatus to a second air conditioning apparatus from among the plurality of air conditioning apparatus based on setting information determined in advance.

9. The computer-readable recording medium according to claim 8, wherein
the setting information indicates rates of the cooling capacity with which the cooling capacity of the first air conditioning apparatus is to be allocated to the second air conditioning apparatus; and
the process further comprises allocating the cooling capacity to the second air conditioning apparatus with the rates of the cooling capacity indicated by the setting information.

10. The computer-readable recording medium according to claim 9, wherein
the setting information includes a plurality of combinations of a number of the plurality of air conditioning apparatus and an installation position of the first air conditioning apparatus and a rate of the cooling capacity to be allocated to each of the second air conditioning apparatus is set for each of the combinations, and
when a failure occurs in a plurality of first air conditioning apparatus from among the plurality of air conditioning apparatus, determining a rate of the cooling capacity to be allocated to each of the second air conditioning apparatus based on two or more ones of the combinations in the setting information corresponding to a relationship of the installation positions between each of the first air conditioning apparatus and each of the second air conditioning apparatus from among the plurality of air conditioning apparatus.

11. The computer-readable recording medium according to claim 9, the process further comprising:
acquiring state information relating to a state of the plurality of electronic apparatus from the plurality of electronic apparatus, and
determining the cooling capacity to be allocated to each of the second air conditioning apparatus based on a total heat generation amount of the plurality of electronic apparatus included in the acquired state information to allocate the cooling capacity to the second air conditioning apparatus with the rates based on the setting information.

12. The computer-readable recording medium according to claim 11, the process further comprising:
determining, from temperatures of the plurality of electronic apparatus included in the state information, after the cooling capacity is allocated to the second air conditioning apparatus whether or not the temperature of one of the plurality of electronic apparatus is higher than a predetermined value; and
adjusting, when it is determined that the temperature of one of the plurality of electronic apparatus is higher than the predetermined value, then the cooling capacity allocated to the second air conditioning apparatus i based on the installation position of the electronic apparatus whose temperature is higher than the predetermined value.

13. The computer-readable recording medium according to claim 11, the process further comprising, when the temperature of the first electronic apparatus from among the plurality of electronic apparatus is higher than a predetermined value from the temperatures of the plurality of electronic apparatus included in the state information, causing the second electronic apparatus from among the plurality of electronic apparatus to execute a process to be executed by the first electronic apparatus.

14. A controlling method for a data center that includes a plurality of electronic apparatus, a plurality of air conditioning apparatus individually corresponding to the plurality of electronic apparatus, and a control apparatus, the method comprising:
controlling, by the control apparatus, a cooling capacity of each of the plurality of air conditioning apparatus; and
allotting, by the control apparatus, when a failure occurs in a first air conditioning apparatus from among the plurality of air conditioning apparatus, a cooling capacity of the first air conditioning apparatus to a second air conditioning apparatus from among the plurality of air conditioning apparatus based on setting information determined in advance.

15. The controlling method according to claim 14, wherein
the setting information indicates rates of the cooling capacity with which the cooling capacity of the first air conditioning apparatus is to be allocated to the second air conditioning apparatus; and
the method further comprises allocating the cooling capacity to the second air conditioning apparatus with the rates of the cooling capacity indicated by the setting information.

16. The controlling method according to claim 15, wherein
the setting information includes a plurality of combinations of a number of the plurality of air conditioning apparatus and an installation position of the first air conditioning apparatus and a rate of the cooling capacity to be allocated to each of the second air conditioning apparatus is set for each of the combinations, and
the method further comprises, when a failure occurs in a plurality of first air conditioning apparatus from among the plurality of air conditioning apparatus, determining, by the control apparatus, a rate of the cooling capacity to be allocated to each of the second air conditioning apparatus based on two or more of the combinations in the setting information corresponding to a relationship of the installation positions between each of the first air conditioning apparatus and each of the second air conditioning apparatus from among the plurality of air conditioning apparatus.

17. The controlling method according to claim 15, the method further comprising:
acquiring, by the control apparatus, state information relating to a state of the plurality of electronic apparatus from the plurality of electronic apparatus; and
determining, by the control apparatus, the cooling capacity to be allocated to each of the second air conditioning apparatus based on a total heat generation amount of the plurality of electronic apparatus included in the acquired state information to allocate the cooling capacity to the second air conditioning apparatus with the rates based on the setting information.

18. The controlling method according to claim 17, the method further comprising:
determining, by the control apparatus, from temperatures of the plurality of electronic apparatus included in the state information after the cooling capacity is allocated to the second air conditioning apparatus whether or not the temperature of one of the plurality of electronic apparatus is higher than a predetermined value; and
adjusting, by the control apparatus, when it is decided that the temperature of one of the plurality of electronic apparatus is higher than the predetermined value, the cooling capacity allocated to the second air conditioning apparatus based on the installation position of the electronic apparatus whose temperature is higher than the predetermined value.

19. The controlling method for a data center according to claim 17, the method further comprising, when the temperature of the first electronic apparatus from among the plurality of electronic apparatus is higher than a predetermined value from the temperatures of the plurality of electronic apparatus included in the state information, causing, by the control apparatus, the second electronic apparatus from among the plurality of electronic apparatus to execute a process to be executed by the first electronic apparatus.
